(19) United States
(12) Patent Application Publication
(10) Pub. No.: US 2006/0154417 A1
(43) Pub. Date: Jul. 13, 2006

(54) Semiconductor memory device

(75) Inventors: Naoyuki Shinmura, Fukuyama-shi (JP); Shigeo Ohnishi, Fukuyama-shi (JP); Tetsuya Ohnishi, Fukuyama-shi (JP); Shinobu Yamazaki, Kasaoka-shi (JP); Takahiro Shibuya, Fukuyama-shi (JP); Takashi Nakano, Fukuyama-shi (JP); Masayuki Tajiri, Fukuyama-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/330,806

(22) Filed: Jan. 11, 2006

(30) Foreign Application Priority Data
Jan. 11, 2005 (JP) JP2005-003799

(51) Int. Cl. H01L 21/8242

(52) U.S. Cl. 438/240; 438/785; 438/253

(57) ABSTRACT

The present invention is directed towards a method of manufacturing a semiconductor memory device arranged of a cross point memory array having memory elements provided between upper and lower electrodes for storage of data. The present invention comprises a lower electrode lines forming step of planarizing each of the lower electrode lines and insulating layers provided on both sides of the lower electrode line so as to be substantially uniform in the height thus for patterning the lower electrode lines, a memory element layer depositing step of depositing on the lower electrode lines a memory element layer for the memory elements, and an annealing step of annealing with heat treatment either between the lower electrode lines forming step and the memory element layer depositing step or after the memory element layer depositing step so that any damages caused by the polishing of the surface of the lower electrode lines can be eliminated.

### CROSS REFERENCE TO RELATED APPLICATTION

This Nonprovisional application claims priority under 35 U.S.C. §119(a) on Patent Application No. 2005-003799 filed in Japan on Jan. 11, 2005, the entire contents of which are hereby incorporated by reference.

### BACKGROUND OF THE INVENTION

1. Field of the Invention

The present invention relates to a method of manufacturing a semiconductor memory device and more particularly to a method of manufacturing a semiconductor memory device arranged of a cross point structure having a plurality of upper electrode lines patterned to extend in one direction, a plurality of lower electrode lines patterned to extend at a right angle to the direction of the upper electrode lines, and memory elements provided between the upper electrode lines and the lower electrode lines for storage of data.

2. Description of the Related Art

A common semiconductor memory device such as DRAM, NOR flash memory, or FeRAM is arranged in which each memory cell consists mainly of a element for storage of data and a select transistor for selecting the memory element. Alternatively, a memory cell of the cross point structure is provided comprising only a memory element provided at the intersection (cross point) between a bit line and a word line for storage of a memory data while excluding the select transistor. Since the memory cell of the cross point structure allows a memory data to be read out directly from the cross point between the selected bit line and the selected word line with the use of no transistor, it can be simple in the construction and minimized in the storage area thus contributing to the scaling up of the memory device regardless of slowdown of the operating speed and increase in the current consumption which may result from the reading current superimposed with a parasitic current received from unselected memory cells connected with the selected bit line or word line.

Some conventional memory devices arranged of the above described cross point structure have been proposed in the form of MRAM (magnetic resistance memory) or FeRAM (ferroelectric memory). For example, disclosed at FIG. 2 in Japanese Patent Laid-open Publication No. 2001-273757 is an MRAM arranged of the cross point structure featuring the effect of ferromagnetic tunneling magneto-resistance (TMR) or a change in the resistance due to the variation in the magnetizing direction. Also disclosed at FIG. 2 in Japanese Patent Laid-open Publication No. 2003-288784 is an FeRAM of the cross point structure featuring the effect of ferro-electricity or a variation in the residual polarization due to the action of an electric field.

Furthermore, disclosed in Japanese Patent Laid-open Publication No. 2003-68984 are a semiconductor memory device of the cross point structure and a method of manufacturing the same in which the memory element for storage of data is made of a perovskite material having a colossal magneto-resistance (CMR) or a change in the resistance due to the action of an electric field.

The method of manufacturing a semiconductor memory device of the cross point structure featuring a change in the resistance caused by the electric field will be explained in brief. FIG. 1 is a plan layout view of memory cells arranged in the cross point structure, where a pattern of lower electrode lines B is denoted by R1 while a pattern of upper electrode lines T is denoted by R2. The upper electrode lines T and the lower electrode lines B are word lines and bit lines respectively or vice versa. FIGS. 18A to 23A and FIGS. 18B to 23B illustrate steps of a conventional method. FIGS. 18A to 23A are vertical cross sectional views taken along the line X-X′ of FIG. 1. Similarly, FIGS. 18B to 23B are vertical cross sectional views taken along the line Y-Y′ of FIG. 1.

The conventional method starts with depositing an interlayer insulating layer 12 under a memory cell on a silicon semiconductor substrate 11 on which transistor circuits (not shown) are patterned and polishing the same by a CMP (chemical mechanical polishing) method to eliminate undulations caused by the pattern of transistor circuits and planarize its surface.

This is followed by depositing over the entire surface of an electrode layer 13 which is turned to the lower electrode lines B, placing a pattern of resist R1 shaped as the mask in a stripe form (lines and spaces) by a photolithographic technique, and etching the electrode layer 13 to pattern the lower electrode lines B, as shown in FIGS. 18A and 18B.

Then, after the resist R1 is removed, the entire surface is coated with an insulating layer 14 which has a generous thickness enough to fill up between the lower electrode lines B, as shown in FIGS. 19A and 19B.

Next, another CMP (chemical mechanical polishing) step follows for polishing down the insulating layer 14 to expose the surface of the lower electrode lines B. As the result, the spaces between the lower electrode lines B are filled with the insulating layer 14 as shown in FIGS. 20A and 20B. As the insulating layer 14 and the lower electrode lines B are substantially equal in the height at the surface, their assembly can substantially be smoothed at the surface. The step of polishing the surface is intended to allow a succeeding resistor layer to be deposited on as the smooth surface as possible. It will otherwise be troublesome to deposit the resistor layer over the stepped surface of the lower electrode layer because the selectable ratio of etching between the resistor layer and the lower electrode layer is not applicable in the succeeding resistor layer etching step.

Then, a perovskite resistor layer 15 (a memory element layer) is deposited over the entire surface which has a CMR effect and is turned to the memory elements for storage of data. This is followed by depositing over the entire surface of an electrode layer 16 which is turned to the upper electrode lines T thus to complete such a structure as shown in FIGS. 21A and 21B.

Another photolithographic step follows for providing a stripe pattern (lines and spaces) of resist R2 as the mask by a photolithographic technique and etching the upper electrode layer 16 to pattern the upper electrode lines T. Then, the remainings of the resistor layer 15 between the upper electrode lines T are removed by etching and such a structure as shown in FIGS. 22A and 22B is completed.

After the resist R2 is removed, an interlayer insulating layer 17 under metal wirings is deposited over the entire surface as shown in FIGS. 23A and 23B. The metal wirings (not shown) are then provided by patterning contacts (not shown) with the transistor circuits excluding the lower electrode lines B, the upper electrode lines T, and the memory cells.

However, there are two drawbacks in the conventional method which will be explained below.

Firstly, as the insulating layer 14 is polished down to ease the steps of the lower electrode lines B shown in FIGS. 20A and 20B in the conventional method, some exposure of the lower electrode lines B to the polishing is inevitable for compensating variations in the thickness of the insulating layer 14 over the lower electrode lines B and in the polishing rate at the silicon substrate. More specifically, the upper surface of the lower electrode lines B is over-polished in order to prevent insufficient polishing down of the insulating layer 14 over the entire silicon substrate (to prevent the insulating layer 14 from remaining on the lower electrode lines B). Particularly, the upper surface of the lower electrode lines B is over-polished more where the insulating layer 14 is thinner or has a faster polishing rate. Such over-polishing may create a damaged layer D1 at the surface of the lower electrode lines B which is fractured in the crystalline properties.

Since the resistor layer is made of a perovskite material, which is variable in the resistance with the effect of electric field, and turned to the memory elements for storage of data, it is preferably deposited on the lower electrode lines B by epitaxial growth (mono-crystalline growth). It is hence crucial to improve the crystalline affinity between the epitaxial layer and the upper surface of the lower electrode liens B. If the resistor layer is deposited on the damaged layer D1 of the lower electrode lines B, it may become nonuniform in the crystalline orientation. Such nonuniformity in the crystalline orientation will result in variations in the resistance and the rate of resistance change, hence lowering the electrical characteristics in the memory action.

As the second drawback of the conventional method, the action of etching the resistor layer 15, which is commonly implemented by an anisotropic dry etching technique as shown in FIGS. 22A and 22B, may create etching damages on the side walls of the resistor layer 15 with its plasma ions. Also, the etching action may trigger different chemical reactions for producing undesired deposits which are then removed with the use of chemical agents. Such chemical agents will consequently damage the side walls of the resistor layer 15.

The damaged layer (D2) of the resistor layer 15 is different in the crystalline properties from the other internal undamaged portions. Also, their level may frequently trap electrical charges. This effect of the damaged layer will make the switching action unstable or decline the degree of data retention. The narrower the lower and upper electrode lines or the smaller the area at each intersection (the cross point) between the lower and upper electrode lines, the more the effect of the damaged layer will be apparent and the more the miniaturization of the electrode lines will be disturbed.

### SUMMARY OF THE INVENTION

The present invention has been developed in view of the foregoing aspects and its object is to provide an improve method of manufacturing a semiconductor memory device of the cross point structure in which the memory element material for storage of data is uniform in the crystalline properties while eliminating any damaged layers which are commonly created by the conventional method.

As the first feature of the present invention for achievement of the above described object, a method of manufacturing a semiconductor memory device which has an array of memory cells arranged in a cross point structure including a plurality of upper electrode lines patterned to extend in one direction, a plurality of lower electrode lines patterned to extend at a right angle to the one direction of the upper electrode lines, and memory elements provided between the upper electrode lines and the lower electrode lines for storage of data, is provided comprising a lower electrode lines forming step of planarizing each of the plurality of lower electrode lines and insulating layers provided on both sides of the lower electrode line so as to be substantially uniform in the height thus for patterning the plurality of lower electrode lines, a memory element layer depositing step of depositing on the plurality of lower electrode lines a memory element layer which is turned to the memory elements, and an annealing step of annealing with heat treatment between the lower electrode lines forming step and the memory element layer depositing step.

As the second feature of the present invention, the method of manufacturing a semiconductor memory device may be modified in which the annealing step is provided after the memory element layer depositing step but not between the two steps.

As the third feature of the present invention, a method of manufacturing a semiconductor memory device which has an array of memory cells arranged in a cross point structure including a plurality of upper electrode lines patterned to extend in one direction, a plurality of lower electrode lines patterned to extend at a right angle to the one direction of the upper electrode lines, and memory elements provided between the upper electrode lines and the lower electrode lines for storage of data, is provided comprising a lower electrode lines forming step of planarizing each of the plurality of lower electrode lines and insulating layers provided on both sides of the lower electrode line so as to be substantially uniform in the height thus for patterning the plurality of lower electrode lines, a memory element layer depositing step of depositing on the plurality of lower electrode lines a memory element layer which is turned to the memory elements, a second electrode layer depositing step of depositing on the memory element layer a second electrode layer which is turned to the upper electrode lines, an upper electrode lines forming step of etching the second electrode layer to pattern the upper electrode lines, a memory elements forming step of etching the memory element layer left between the upper electrode lines to pattern the memory elements, and another annealing step of annealing with heat treatment after the memory elements forming step.

The method of manufacturing a semiconductor memory device may also be modified in which the heat treatment in the annealing step is carried out at a heating temperature ranging from 300° C. to 800° C.

The method of manufacturing a semiconductor memory device may further be modified in which the lower electrode lines forming step comprises the sub steps of depositing on a semiconductor substrate a first electrode layer which is turned to the lower electrode lines, etching the first electrode layer to pattern the lower electrode lines, depositing the insulating layer on the lower electrode lines, and polishing down the insulating layer until the lower electrode lines are exposed at the upper surface, or the sub steps of depositing the insulating layer on a semiconductor substrate, processing the insulating layer to have a stripe form of steps, depositing on the insulating layer with the steps a first electrode layer which is turned to the lower electrode lines, and polishing down the first electrode layer until the insulating layer is exposed at the upper surface.

The method of manufacturing a semiconductor memory device may further be modified in which the memory element layer is made of a perovskite oxide material which includes at least one element selected from Pr, Ca, La, Sr, Gd, Nd, Bi, Ba, Y, Ce, Pb, Sm, and Dy and at least another element selected from Ta, Ti, Cu, Mn, Cr, Co, Fe, Ni, and Ga.

The method of manufacturing a semiconductor memory device may further be modified in which the memory element layer is made of a perovskite oxide material which is expressed by any one of formulas (where 0≦x≦1 and 0≦z<1) selected from Pr_{1-X}Ca_{X}[Mn_{1-Z}M_{Z}]O₃ (M being any one of elements selected from Cr, Co, Fe, Ni, and Ga), La_{1-X}AE_{X}MnO₃ (AE being any one of bivalent alkali earth metals selected from Ca, Sr, Pb, and Ba), RE_{1-X}Sr_{X}MnO₃ (RE being any one of trivalent rare earth elements selected from Sm, La, Pr, Nd, Gd, and Dy), La_{1-X}Co_{X}[Mn_{1-Z}Co_{Z}]O₃, Gd_{1-X}Ca_{X}MnO₃, and Nd_{1-X}Gd_{X}MnO₃.

The method of manufacturing a semiconductor memory device may further be modified in which the material of the upper electrode lines contains at least one selected from a noble metal of platinum group metals, a metal selected from Ag, Al, Cu, Ni, Ti, and Ta, or an alloy of the metal, an electrically conductive oxide of Ir, Ru, Re, or Os, and another electrically conductive oxide selected from SRO(SrRuO₃), LSCO((LaSr)CoO₃), and YBCO(YbBa₂Cu₃O₇).

In the method of manufacturing a semiconductor memory device according to the present invention, the annealing step is provided for eliminating the damaged layer D1 at the surface of the lower electrode lines and thus allows the resistor layer to be deposited as an epitaxial thin film over the lower electrode lines. As the result, variations in the resistance depending largely on the crystalline properties of the resistor layer will be minimized.

Also, in the method of manufacturing a semiconductor memory device according to the present invention, another annealing step is provided for modifying the resistor layer deposited over the damaged layer D1 at the surface of the lower electrode lines to be equal to the quality of an epitaxial thin film. Equally, unwanted variations in the resistance will be minimized.

Moreover, in the method of manufacturing a semiconductor memory device according to the present invention, the annealing step is provided for eliminating the damaged layer D2 at the side walls of the resistor layer and thus allows the resistor layer to be deposited uniformly in the properties throughout the cross point areas. Since its dependency on the width of the electrode lines is minimized, the device can be improved in the miniaturization.

### BRIEF DESCRIPTION OF THE DRAWINGS

FIG. 1A and FIG. 1B are plan layout views of an array of memory cells at the cross point structure;

FIG. 2A and FIG. 2B are cross sectional views showing steps of the first embodiment of the method of manufacturing a semiconductor memory device according to the present invention;

FIG. 3A and FIG. 3B are cross sectional views showing further steps of the first embodiment of the method of manufacturing a semiconductor memory device according to the present invention;

FIG. 4A and FIG. 4B are cross sectional views showing further steps of the first embodiment of the method of manufacturing a semiconductor memory device according to the present invention;

FIG. 5A and FIG. 5B are cross sectional views showing further steps of the first embodiment of the method of manufacturing a semiconductor memory device according to the present invention;

FIG. 6A and FIG. 6B are cross sectional views showing further steps of the first embodiment of the method of manufacturing a semiconductor memory device according to the present invention;

FIG. 7A and FIG. 7B are cross sectional views showing further steps of the first embodiment of the method of manufacturing a semiconductor memory device according to the present invention;

FIG. 8A and FIG. 8B are cross sectional views showing steps of the second embodiment of the method of manufacturing a semiconductor memory device according to the present invention;

FIG. 9A and FIG. 9B are cross sectional views showing further steps of the second embodiment of the method of manufacturing a semiconductor memory device according to the present invention;

FIG. 10A and FIG. 10B are cross sectional views showing further steps of the second embodiment of the method of manufacturing a semiconductor memory device according to the present invention;

FIG. 11A and FIG. 11B are cross sectional views showing further steps of the second embodiment of the method of manufacturing a semiconductor memory device according to the present invention;

FIG. 12A and FIG. 12B are cross sectional views showing further steps of the second embodiment of the method of manufacturing a semiconductor memory device according to the present invention;

FIG. 13A and FIG. 13B are cross sectional views showing steps of the third embodiment of the method of manufacturing a semiconductor memory device according to the present invention;

FIG. 14A and FIG. 14B are cross sectional views showing further steps of the third embodiment of the method of manufacturing a semiconductor memory device according to the present invention;

FIG. 15A and FIG. 15B are cross sectional views showing steps of the fourth embodiment of the method of manufacturing a semiconductor memory device according to the present invention;

FIG. 16A and FIG. 16B are cross sectional views showing further steps of the fourth embodiment of the method of manufacturing a semiconductor memory device according to the present invention;

FIG. 17A and FIG. 17B are cross sectional views showing further steps of the fourth embodiment of the method of manufacturing a semiconductor memory device according to the present invention;

FIG. 18A and FIG. 18B are cross sectional views showing steps of a conventional method of manufacturing a semiconductor memory device of the cross point structure;

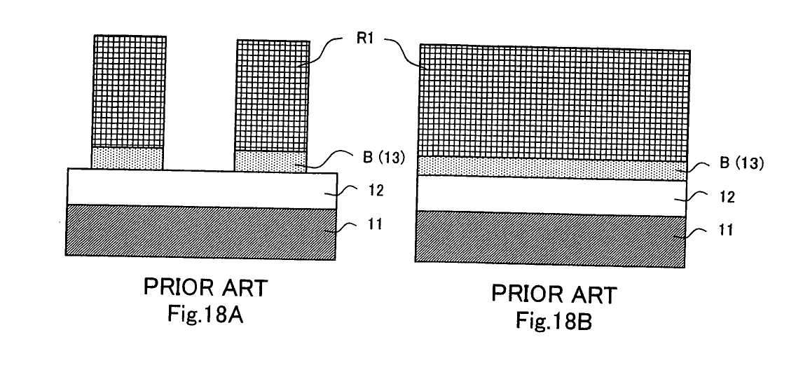

FIG. 19A and FIG. 19B are cross sectional views showing further steps of the conventional method of manufacturing a semiconductor memory device of the cross point structure;

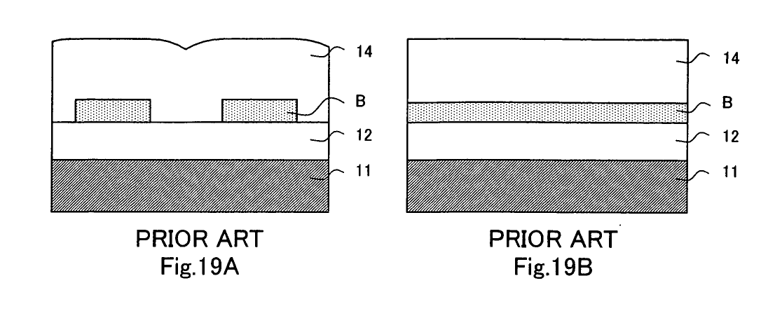

FIG. 20A and FIG. 20B are cross sectional views showing further steps of the conventional method of manufacturing a semiconductor memory device of the cross point structure;

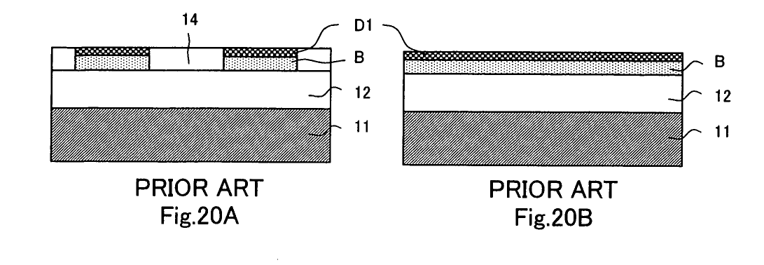

FIG. 21A and FIG. 21B are cross sectional views showing further steps of the conventional method of manufacturing a semiconductor memory device of the cross point structure;

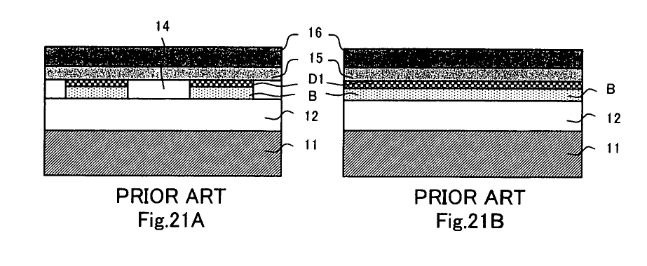

FIG. 22A and FIG. 22B are cross sectional views showing further steps of the conventional method of manufacturing a semiconductor memory device of the cross point structure;

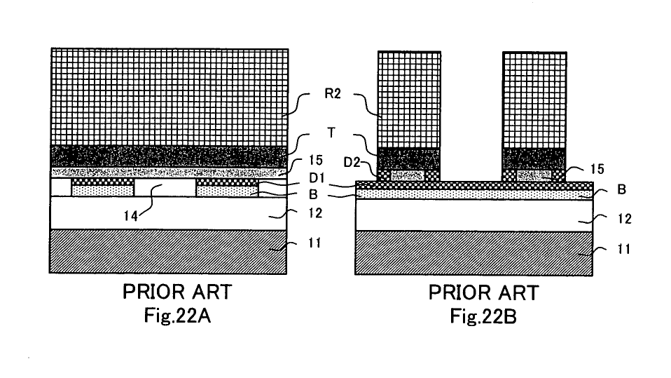

FIG. 23A and FIG. 23B are cross sectional views showing further steps of the conventional method of manufacturing a semiconductor memory device of the cross point structure;

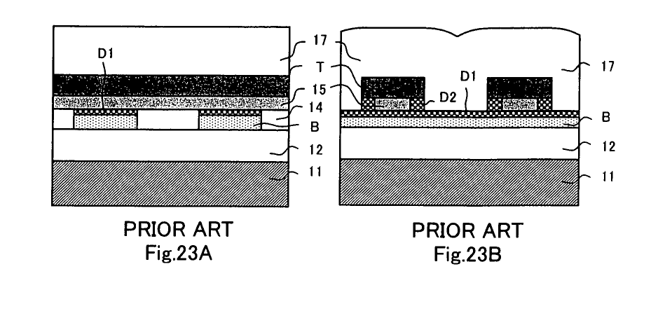

FIG. 24 is a graph explaining the advantage of an annealing step in the first embodiment of the method of manufacturing a semiconductor memory device according to the present invention; and

FIG. 25 is a graph explaining the advantage of an annealing step in the fourth embodiment of the method of manufacturing a semiconductor memory device according to the present invention.

### DETAILED DESCRIPTION OF THE INVENTION

A method of manufacturing a semiconductor memory device arranged of a cross point structure according to the present invention (referred to as the inventive method hereinafter) will be described in the form of four different embodiments, referring to the relevant drawings.

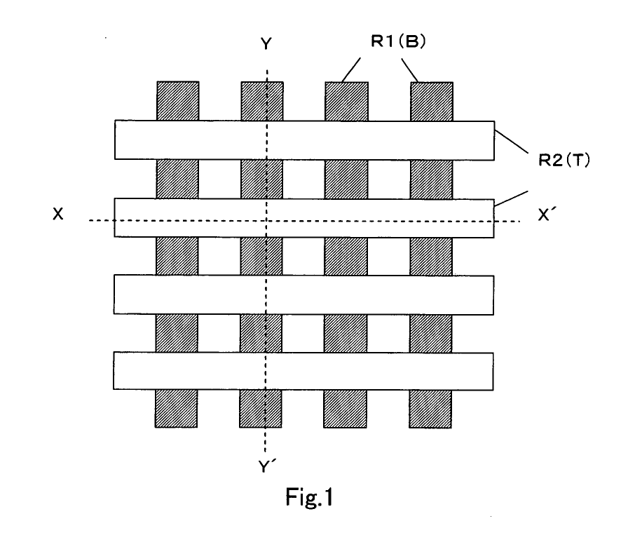

FIG. 1 is a plan layout view of an array of memory cells manufactured by the inventive method, where a pattern of lower electrode lines B is denoted by R1 while a pattern of upper electrode lines T is denoted by R2. The plan layout view illustrates the array of memory cells arranged equal to a conventional cross point structure. It is now noted in the description of the four embodiments of the inventive method that the memory device to be manufactured is a resistance RAM (RRAM) having a plurality or an array of memory cells arranged in a cross point structure where the material of each memory cell is a CMR material (for example, PCMO:Pr_{0.7}Ca_{0.3}MnO₃) in thin layer form.

(First Embodiment)

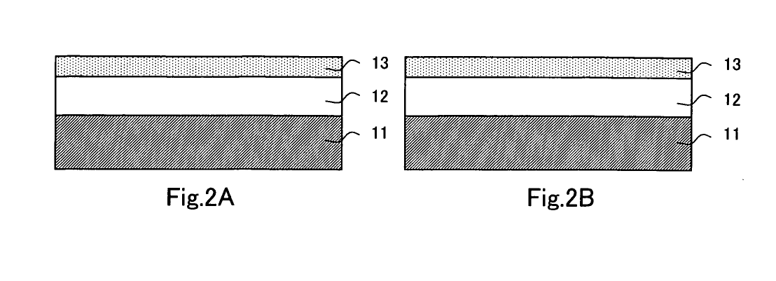

FIGS. 2A to 7A and FIGS. 2B to 7B illustrate steps of the inventive method showing the first embodiment of the present invention. FIGS. 2A to 7A are vertical cross sectional views taken along the line X-X′ of FIG. 1. Similarly, FIGS. 2B to 7B are vertical cross sectional views taken along the line Y-Y═ of FIG. 1. The term “vertical” in this specification means a direction vertical to the surface of a semiconductor substrate 11 unless otherwise specified.

The procedure starts with, similar to the conventional method, depositing a BPSG layer 12 to a thickness of 1300 nm, which serves as the interlayer insulating layer under a memory cell, on the silicon semiconductor substrate 11 on which transistor circuits (not shown) are patterned and polishing the same to a thickness of 600 nm by a CMP (chemical mechanical polishing) technique to planarize its surface. Then as shown in FIGS. 2A and 2B, a sputtering step is conducted for depositing a Pt layer 13 (acting as the first electrode layer) which is turned to the lower electrode lines B to a thickness of 200 nm specifically in this embodiment.

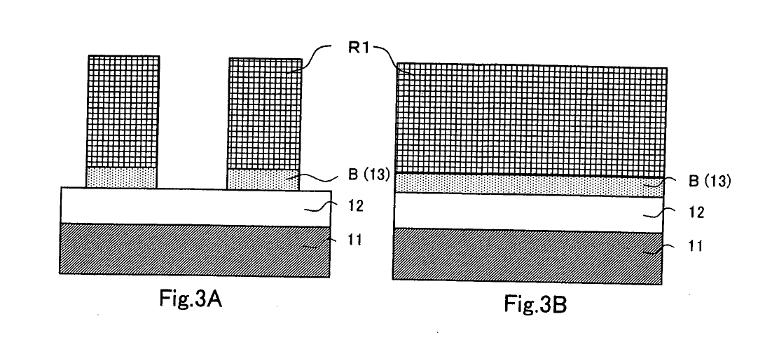

This is followed by, as shown in FIGS. 3A and 3B, placing a pattern of resist R1 shaped as the mask in a stripe form (lines and spaces) by a photolithographic technique and etching the Pt layer 13 to form the lower electrode lines B. In this embodiment, the resist R1 used for the etching is patterned in stripes of 0.3 μm wide spaced 0.3 μm from one another.

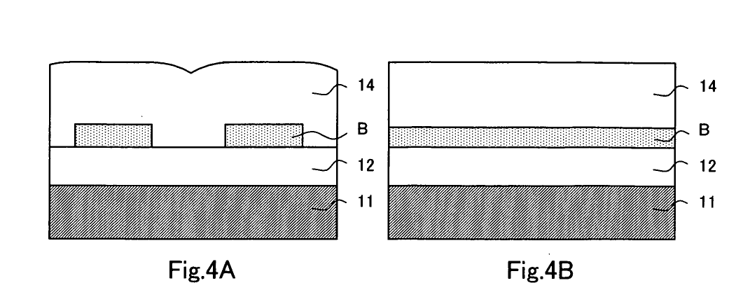

Then, after the resist R1 is removed, a silicon oxide layer 14 is deposited over the entire surface to a generous thickness for allowing the lower electrode lines B to be embedded therein, as shown in FIGS. 4A and 4B. In this embodiment, the thickness of the silicon oxide layer 14 is 400 nm.

Next, another CMP (chemical mechanical polishing) step follows for polishing down the silicon oxide layer 14 to expose the surface of the lower electrode lines B. As the result, the steps of providing the lower electrode lines B are completed.

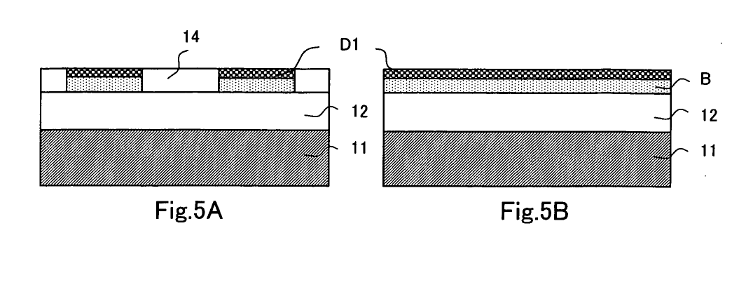

More particularly at the polishing step in the process of providing the lower electrode lines B, the silicon oxide layer 14 is polished down to be substantially equal in the height to the surface of the lower electrode lines B which have been embedded therein, as shown in FIGS. 5A and 5B, thus developing a planar surface structure in which the surfaces are substantially flush with one another. However, the polishing step at the last may generate a damaged layer D1 at the surface of the lower electrode lines B, which is fractured in the crystalline structure as schematically shown in FIGS. 5A and 5B.

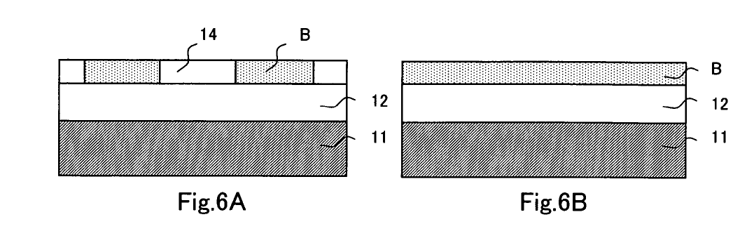

Accordingly, an annealing step is provided for amending the damaged layer D1. In this embodiment, the annealing step is carried out at a temperature of 500° C. under the normal pressure (1013 Pa) in an N₂ gas atmosphere for thirty minutes. After the annealing step, the damaged layer D1 is eliminated from the surface of the lower electrode lines B as schematically shown in FIGS. 6A and 6B. In other words, the crystalline structure can favorably be recovered at the surface of the lower electrode lines B.

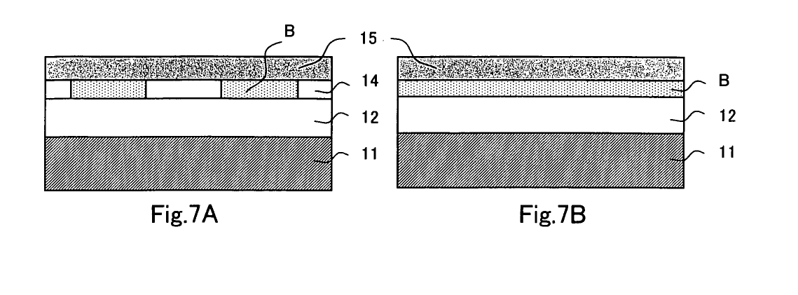

This is followed by covering the lower electrode lines B and the silicon oxide layer 14 with a resistor layer 15 made of a PCMO material (Pr_{0.7}Ca_{0.3}MnO₃) for developing a memory element (memory element layer depositing step), as shown in FIGS. 7A and 7B. Because the damaged layer D1 has been eliminated, the memory element layer depositing step in this embodiment permits the resistor layer 15 to be deposited as an epitaxial (mono-crystalline) thin film which is uniform in the crystalline orientation.

(Second Embodiment)

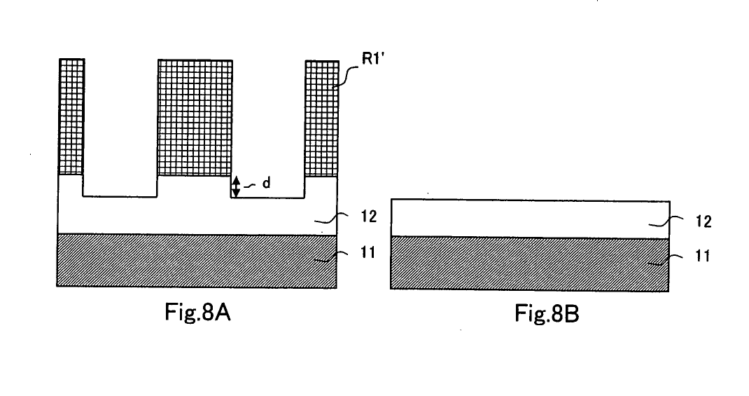

The second embodiment of the inventive method will now be described referring to the relevant drawings. The second embodiment is a modification of the first embodiment and particularly, its step of providing the lower electrode lines B is different from that of the first embodiment. FIGS. 8A to 12A and FIGS. 8B to 12B illustrate steps of the inventive method of the second embodiment. FIGS. 8A to 12A are vertical cross sectional views taken along the line X-X′ of FIG. 1. Similarly, FIGS. 8B to 12B are vertical cross sectional views taken along the line Y-Y′ of FIG. 1.

The procedure starts with, similar to the conventional method, depositing a BPSG layer 12 to a thickness of 1300 nm, which serves as the interlayer insulating layer under a memory cell, on the silicon semiconductor substrate 11 on which transistor circuits (not shown) are patterned and polishing the same to a thickness of 800 nm by a CMP (chemical mechanical polishing) technique to planarize its surface. Then as shown in FIGS. 8A and 8B, a step follows for placing a pattern of resist R1′ shaped as the mask in a stripe form (lines and spaces) by a photolithographic technique and etching the BPSG layer 12 to form recesses of d in the depth (pits and lands in a stripe form) in the surface. In this embodiment, the resist R1′ used for the etching is patterned in stripes of 0.3 Am wide spaced 0.3 μm from one another and the etching is so controlled that the depth d is 200 nm.

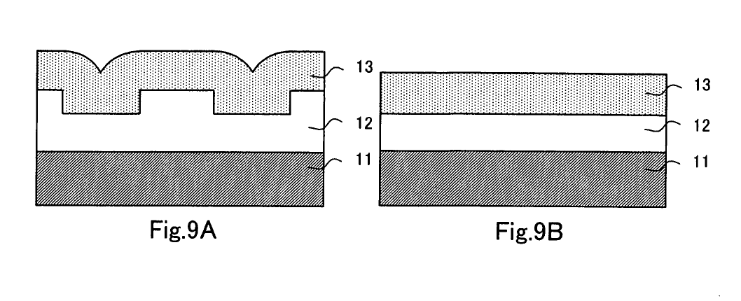

Then, after the resist R1′ is removed, a Pt layer 13 (acting as the first electrode layer) is deposited over the entire surface of the BPSG layer 12 to a generous thickness for allowing the recesses in the surface to be filled up and shaped of the lower electrode lines B, as shown in FIGS. 9A and 9B. In this embodiment, the thickness of the Pt layer 13 is 300 nm.

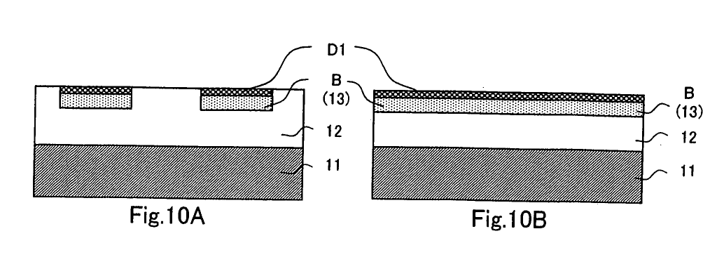

Next, another CMP (chemical mechanical polishing) step follows for polishing down the Pt layer 13 to the interlayer insulating layer surface level until the lower electrode lines B are shaped in the recesses of the BPSG layer 12, as shown in FIGS. 10A and 10B. As the result, the steps of providing the lower electrode lines B are completed. However, the polishing step at the last may generate a damaged layer D1 at the surface of the lower electrode lines B, which is fractured in the crystalline structure as schematically shown in FIGS. 10A and 10B.

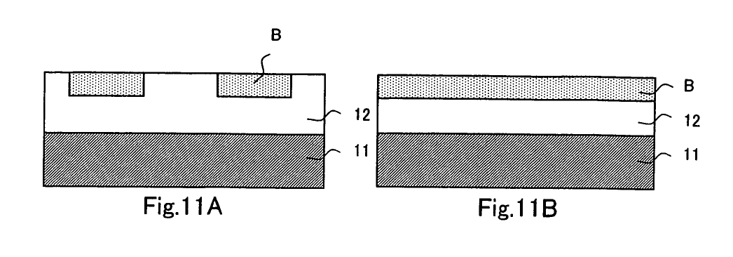

Accordingly, an annealing step similar to that of the first embodiment is provided for amending the damaged layer D1. In this embodiment, the annealing step is carried out at a temperature of 500° C. under the normal pressure (1013 Pa) in an N₂ gas atmosphere for thirty minutes. After the annealing step, the damaged layer D1 is eliminated from the surface of the lower electrode lines B as schematically shown in FIGS. 11A and 11B. In other words, the crystalline structure can favorably be recovered at the surface of the lower electrode lines B.

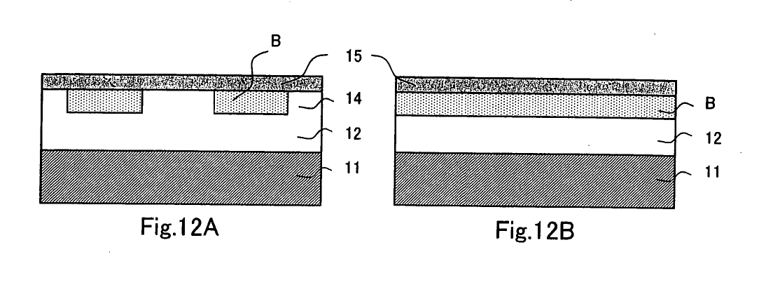

This is followed by covering the lower electrode lines B and the silicon oxide layer 14 with a resistor layer 15 made of a PCMO material (Pr_{0.7}Ca_{0.3}MnO₃) for developing a memory element (memory element layer depositing step), as shown in FIGS. 12A and 12B. Because the damaged layer D1 has been eliminated, the memory element layer depositing step in this embodiment permits the resistor layer 15 to be deposited as an epitaxial (mono-crystalline) thin film which is uniform in the crystalline orientation.

(Third Embodiment)

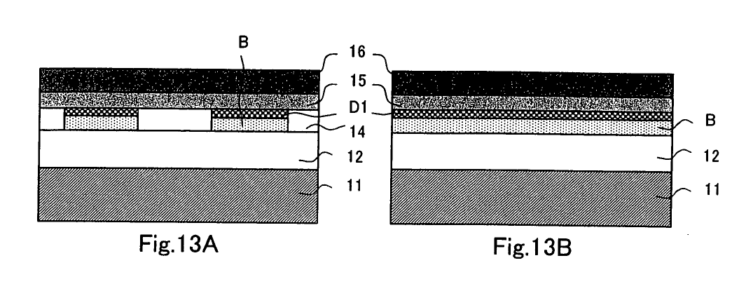

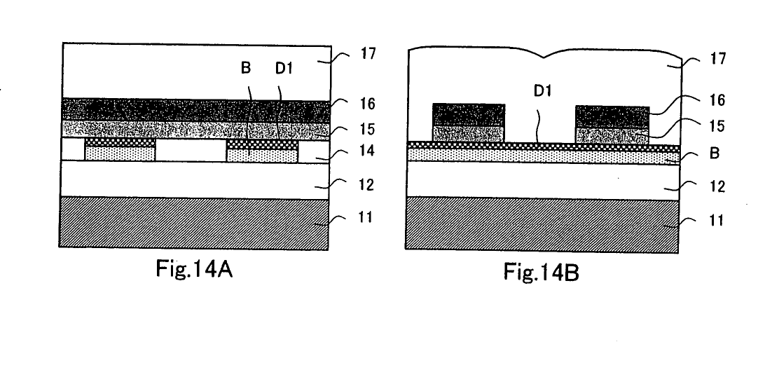

The third embodiment of the inventive method will then be described referring to the relevant drawings. The third embodiment is a modification of the first or second embodiment and particularly, its annealing step is different in both the order and the purpose from that of the first or second embodiment. FIGS. 13A and 14A and FIGS. 13B and 14B illustrate summary steps of the inventive method of the third embodiment. FIGS. 13A and 14A are vertical cross sectional views taken along the line X-X′ of FIG. 1. Similarly, FIGS. 13B and 14B are vertical cross sectional views taken along the line Y-Y of FIG. 1.

The procedure starts with the step of providing the lower electrode lines B similar to that of the first or second embodiment and then depositing a resistor (PCMO) layer 15 made of a PCMO material (Pr_{0.7}Ca_{0.3}MnO₃) for developing a memory element over the semiconductor substrate provided with the lower electrode lines B or a combination of the lower electrode lines B and the silicon oxide layer 14 (the memory element layer depositing step).

This is followed by further depositing a Pt layer 16 (acting as the second electrode layer) which are patterned to a row of upper electrode lines T (the second electrode layer depositing step). In this embodiment, the construction shown in FIGS. 13A and 13B is completed when the lower electrode lines B patterned by the lower electrode lines forming step and the silicon oxide layer 14 have been coated at the upper surface with the PCMO layer 15 of 100 nm thick and succeedingly the Pt layer 16 of 200 nm thick.

However, as different from the first or second embodiment, the third embodiment permits the memory element depositing step not to be preceded by the annealing step, hence causing the PCMO layer 15 to be hardly uniform in the crystalline orientation due to the effect of the damaged layer D1 at the surface of the lower electrode lines B.

Accordingly, an annealing step is provided right after the deposition of the Pt layer 16 for modifying the PCMO layer 15 to an epitaxial (mono-crystalline) form which is uniform in the crystalline orientation. In this embodiment, the annealing step is carried out at a temperature of 500° C. under the normal pressure (1013 Pa) in an N₂ gas atmosphere for thirty minutes. Although the annealing step needs not to be preceded by the deposition of the Pt layer 16, it may be anytime after the deposition of the PCMO layer 15. For example, the annealing step may follow when the construction shown in FIGS. 14A and 14B has been completed or an interlayer insulating layer 17 under metal wirings has been deposited over the upper-electrode lines T provided by patterning the Pt layer 16.

(Fourth Embodiment)

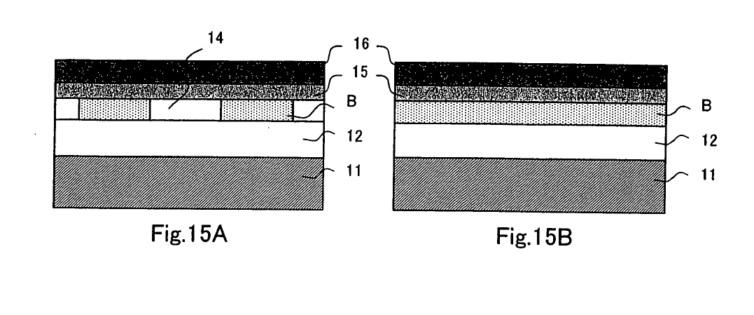

The fourth embodiment of the inventive method will then be described referring to the relevant drawings. The fourth embodiment resides in post steps in any of the first to third embodiments, where the steps up to the deposition of the Pt layer 16 which is turned to the upper electrode lines T are equal to those of any of the first to third embodiments. FIGS. 15A and 15B to FIGS. 17A to 17B illustrate the post steps of the inventive method of the fourth embodiment. FIGS. 15A to 17A are vertical cross sectional views taken along the line X-X′ of FIG. 1. Similarly, FIGS. 15B to 17B are vertical cross sectional views taken along the line Y-Y′ of FIG. 1.

The procedure starts with the step of providing the lower electrode lines B similar to that of the first or second embodiment and then depositing a resistor (PCMO) layer 15 made of a PCMO material (Pr_{0.7}Ca_{0.3}Mn₃) for developing a memory element over the semiconductor substrate provided with the lower electrode lines B or a combination of the lower electrode lines B and the silicon oxide layer 14 (the memory element layer depositing step). In this embodiment, the annealing step equal to that of the first or second embodiment is provided before the deposition of the PCMO layer 15, thus allowing the PCMO layer 15 to be free from the effect of the damaged layer D1 over the lower electrode lines B and deposited in an epitaxial (mono-crystalline) form which is uniform in the crystalline orientation.

This is followed by further depositing a Pt layer 16 (acting as the second electrode layer) which are patterned to a row of upper electrode lines T (the second electrode layer depositing step). In this embodiment, the construction shown in FIGS. 15A and 15B is completed when the lower electrode lines B patterned by the lower electrode lines forming step and the silicon oxide layer 14 have been deposited at the upper surface with the PCMO layer 15 of 100 nm thick and succeedingly the Pt layer 16 of 200 nm thick.

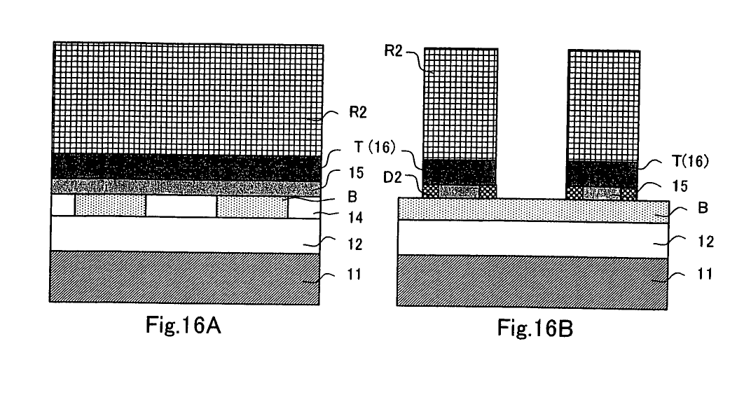

Next, as shown in FIGS. 16A and 16B, a photolithographic step follows to place a pattern of resist R2 shaped as the mask in a stripe form (lines and spaces) and an etching step is conducted to etch down the Pt layer 16 and the PCMO layer 15 to pattern the upper electrode lines T and the memory elements (the upper electrode lines forming step and the memory element forming step). In this embodiment, the resist R2 used for the etching is patterned in stripes of 0.3 μm wide spaced 0.3 μm from one another. However, after the memory element forming step, an etching damaged layer D2 may be developed on the side walls of the PCMO layer 15 by an etching treatment.

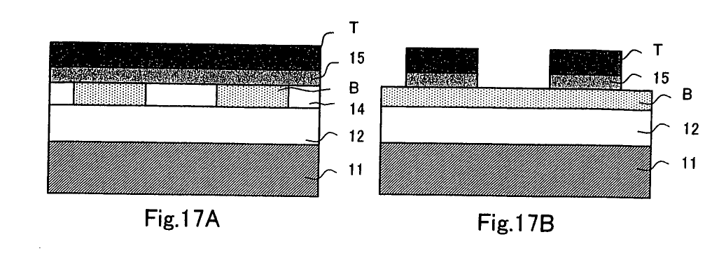

Then, after the resist R2 is removed, another annealing step is provided for amending the damaged layer D2. In this embodiment, the annealing step is carried out at a temperature of 500° C. under the normal pressure (1013 Pa) in an N₂ gas atmosphere for thirty minutes. After the annealing step, the damaged layer D2 is eliminated from the side walls of the PCMO layer 15 as schematically shown in FIGS. 17A and 17B. In other words, the memory element layer which is uniform in the crystalline orientation can be developed throughout the cross point region.

The advantages of the cross point structure of the memory cells manufactured by the inventive method will now be described in comparison with that of the conventional method.

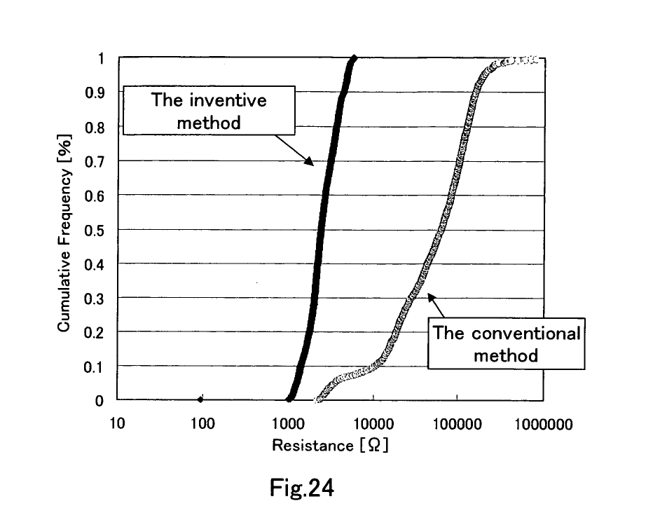

FIG. 24 illustrates profiles of the resistance in the resistor layer produced by the inventive method of the first embodiment and the resistor layer produced by the conventional method respectively. As apparent from FIG. 24, the resistor layer produced by the conventional method exhibits as high variations as about three digits in the resistance. This may result from non-uniformity of the crystalline orientation in the resistor layer due to the damaged layer of surface over the lower electrode lines. Since the inventive method provides the annealing step for eliminating the effect of damages, it can favorably attenuate the variation in the resistance in the resistor layer to as a low level as one digit. Also, its resistor layer is lower in the resistance as developed close to an epitaxial thin film. The inventive method of the second embodiment is different simply in the lower electrode lines forming step and can thus provide the same advantages. The inventive method of the third embodiment includes the annealing step for modifying the resistor layer deposited on the polishing damaged layer over the lower electrode lines to be close to the quality of an epitaxial thin film and can thus provide the same advantages.

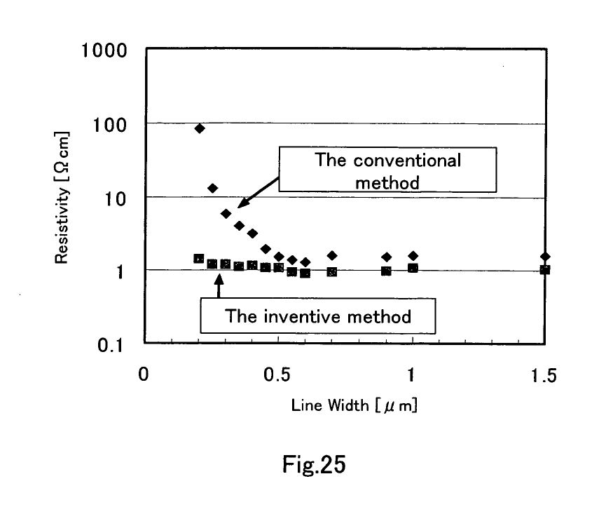

FIG. 25 is a plotted graph showing the relationship between the resistivity of the resistor layer in a memory cell and the line width (of the upper and lower electrode lines) at the cross point in the cross point structure. The resistivity is a physical rate expressed by the following equation as determined by the quality of the material of the resistor layer, thus remaining uniform in relation to the line width.
(Resistivity)=(Resistance of resistor element)×(Area of cross point region)÷(Thickness of resistor layer)

As apparent from FIG. 25, the memory cells manufactured by the conventional method are increased in the resistivity as the line width becomes smaller. This may result from the fact that the damaged area which is different in the quality from the epitaxial layer is increased in the percentage as the line width becomes smaller. The memory cells manufactured by the inventive method of the fourth embodiment are uniform in the resistivity in relation to the line width. This may be explained by the fact that when the unwanted portions of the resistor layer between the upper electrode lines have been removed by the etching action at the upper electrode lines forming step and the memory element forming step, the annealing step is conducted for eliminating the damaged layer from the side walls of the resistor layer thus to make the properties of the resistor layer uniform throughout the cross point regions.

As set forth above, the present invention eliminates unwanted damaged layers which interrupt the quality of the resistor layer, thus minimizing variations in the resistance and attenuating the dependency of the resistor layer on the width of the electrode lines. In addition, it is expected to improve the switching property and data retention property of the memory cell by the aforementioned effects.

Further embodiments of the present invention will be described.

In each of the first to fourth embodiments, the PCMO layer is used as the layer material of the memory element for storage of data but intended not to be so limited. The memory element layer may be made of any other oxide material in a perovskite structure than the PCMO layer which includes at least one element selected from Pr, Ca, La, Sr, Gd, Nd, Bi, Ba, Y, Ce, Pb, Sm, and Dy and at least anoher element selected from Ta, Ti, Cu, Mn, Cr, Co, Fe, Ni, and Ga. More particularly, the memory element layer may be made of a perovskite oxide material which is expressed by any one of formulas (where 0≦x≦1 and 0≦z<1) selected from Pr_{1-X}Ca_{X}[Mn_{1-Z}M_{Z}]O₃ (M being any one of elements selected from Cr, Co, Fe, Ni, and Ga), La_{1-X}AE_{X}MnO₃ (AE being any one of bivalent alkali earth metals selected from Ca, Sr, Pb, and Ba), RE_{1-X}Sr_{X}MnO₃ (RE being any one of trivalent rare earth elements selected from Sm, La, Pr, Nd, Gd, and Dy), La_{1-X}Co_{X}[Mn_{1-Z}Co_{Z}]O₃, Gd_{1-X}Ca_{X}MnO₃, and Nd_{1-X}Gd_{X}MnO₃. Also, the inventive method may be effective for manufacturing memory cells of the cross point structure with the use of any other memory element material than the above described perovskite oxide materials.

The Pt layer in each of the first to fourth embodiments is used for producing the upper electrode lines and the lower electrode lines but intended not to be so limited. Preferably, for example, the lower electrode lines may contain at least one selected from a noble metal of platinum group metals, an alloy of the noble metal, an electrically conductive oxide of Ir, Ru, Re, or Os, and another electrically conductive oxide selected from SRO(SrRuO₃), LSCO((LaSr)CoO₃), and YBCO(YbBa₂Cu₃O₇). Similarly, the upper electrode lines may preferably contain at least one selected from a noble metal of platinum group metals, a metal selected from Ag, Al, Cu, Ni, Ti, and Ta, or an alloy of the metal, an electrically conductive oxide of Ir, Ru, Re, or Os, and another electrically conductive oxide selected from SRO(SrRuO₃), LSCO((LaSr)CoO₃), and YBCO(YbBa₂Cu₃O₇).

In the annealing step in each of the first to fourth embodiments, any condition of a heat treatment is arranged to conduct at a temperature of 500° C. under the normal pressure (1013 Pa) in an N₂ gas atmosphere for thirty minutes but intended not to be so limited. For example, the annealing atmosphere may be filled with a non-oxidizing gas such as Ar gas. Alternatively, when the upper and lower electrode materials are resistant to oxidation, an oxidizing gas such as O₂ may be employed with equal success. Also, a mixture of those gases may be used. The annealing temperature (for heating up) may be not lower than 300° C. for amending the damaged layers. The higher the annealing temperature, the shorter the consumption of time required for amending the damaged layers will be. When the temperature exceeds 800° C., it may decline the characteristics of the transistor circuits. Accordingly, the annealing temperature is preferably within a range from 300° C. to 800° C., including 500° C.

In the fourth embodiment, the upper electrode lines forming step and the lower electrode lines forming step are provided for etching the upper electrode layer and the resistor layer with the use of a stripe pattern of resist R2 but intended not to be so limited. For example, as shown in FIG. 15, a material for masking may be deposited over the entire surface of the second electrode layer which is turned to the upper electrode lines, is patterned to a desired stripe shape with the patterned resist R2, and after the resist R2 is removed, used as a stripe patterned mask for etching the upper electrode layer and the resistor layer. The advantages of the inventive method will never be affected by either the presence or absence of the resist during the step of etching the resistor layer.

In the fourth embodiment, prior to the step of depositing the resistor layer, the lower electrode lines forming step of the first or second embodiment is carried out for developing the lower electrode lines B and followed by the annealing step of the first or second embodiment. The step of depositing the resistor layer may be conducted just after the lower electrode lines forming step, similar to the third embodiment, but before the annealing step. For example, the step of depositing the Pt layer which is turned to the upper electrode lines may be followed by the annealing step of the third embodiment.

Moreover, in the first embodiment, the silicon oxide layer is used as an insulating layer filling between the lower electrode lines but intended not to be so limited. The insulating layer may be, for example, an SiN layer or an SiON layer. Since any of the insulating layers fails to stop over-polishing to the lower electrode lines during the step of polishing down the insulating layer, the inventive method can be advantageous.

Although the present invention has been described in terms of the preferred embodiment, it will be appreciated that various modifications and alternations might be made by those skilled in the art without departing from the spirit and scope of the invention. The invention should therefore be measured in terms of the claims which follow.

1. A method of manufacturing a semiconductor memory device which has an array of memory cells arranged in a cross point structure including a plurality of upper electrode lines patterned to extend in one direction, a plurality of lower electrode lines patterned to extend at a right angle to the one direction of the upper electrode lines, insulating layers provided on both sides of the lower electrode lines, and memory elements provided between the upper electrode lines and the lower electrode lines for storage of data, comprising:
forming the lower electrode lines by planarizing each of the lower electrode lines and the insulating layers provided on both sides of the lower electrode line so as to be substantially uniform in the height and suitable for patterning of the lower electrode lines;
depositing a memory element layer by depositing on the lower electrode lines a memory element layer which is formed into to the memory elements; and
annealing by annealing with heat treatment after the lower electrode lines forming step and before the memory element layer depositing step.

2. The method of manufacturing a semiconductor memory device according to claim 1, wherein
the heat treatment in the annealing step is carried out at a heating temperature ranging from 300° C. to 800° C.

3. The method of manufacturing a semiconductor memory device, according to claim 1, further comprising:
depositing second electrode by depositing on the memory element layer a second electrode layer which is formed into to the upper electrode lines;
forming the upper electrode lines by etching the second electrode layer to pattern the upper electrode lines;
forming the memory elements by etching the memory element layer remaining between the upper electrode lines to pattern the memory elements; and
a second annealing by annealing with heat treatment after the memory elements forming step.

4. The method of manufacturing a semiconductor memory device, according to claim 3, wherein
the heat treatment in the second annealing step after the memory elements forming step is carried out at a heating temperature ranging from 300° C. to 800° C.

5. The method of manufacturing a semiconductor memory device, according to claim 1, wherein
forming the lower electrode lines comprises the sub steps of:
depositing on a semiconductor substrate a first electrode layer which is formed into the lower electrode lines;
etching the first electrode layer to pattern the lower electrode lines;
depositing the insulating layer on the lower electrode lines; and
polishing down the insulating layer until the lower electrode lines are exposed at the upper surface.

6. The method of manufacturing a semiconductor memory device, according to claim 1, wherein
forming the lower electrode lines comprises the sub steps of:
depositing the insulating layer on a semiconductor substrate;
processing the insulating layer to have a stripe form of steps;
depositing on the insulating layer with the stripe form of steps a first electrode layer which is formed into the lower electrode lines; and
polishing down the first electrode layer until the insulating layer is exposed at the upper surface.

7. The method of manufacturing a semiconductor memory device, according to claim 1, wherein
the memory element layer is made of a perovskite oxide material which includes at least one element selected from the group consisting of Pr, Ca, La, Sr, Gd, Nd, Bi, Ba, Y, Ce, Pb, Sm, and Dy and at least another element selected from the group consisting of Ta, Ti, Cu, Mn, Cr, Co, Fe, Ni, and Ga.

8. The method of manufacturing a semiconductor memory device, according to claim 1, wherein
the memory element layer is made of a perovskite oxide material which is expressed by any one of formulas (where 0≦x≦1 and 0≦Z≦1) selected from the group consisting of:
Pr_{1-X}Ca_{X}[Mn_{1-Z}M_{Z}]O₃ (M being any one of elements selected from Cr, Co, Fe, Ni, and Ga),
La_{1-X}AE_{X}MnO₃ (AE being any one of bivalent alkali earth metals selected from Ca, Sr, Pb, and Ba),
RE_{1-X}Sr_{X}MnO₃ (RE being any one of trivalent rare earth elements selected from Sm, La, Pr, Nd, Gd, and Dy),
La_{1-X}Co_{X}[Mn_{1-Z}Co_{Z}]O₃,
Gd_{1-X}Ca_{X}MnO₃, and
Nd_{1-X}Gd_{X}MnO₃.

9. The method of manufacturing a semiconductor memory device, according to claim 1, wherein
the material of the lower electrode lines contains at least one material selected from the group consisting of a noble metal of platinum group metals; an alloy of the noble metal; an electrically conductive oxide of Ir, Ru, Re, or Os; SRO(SrRuO₃), LSCO((LaSr)CoO₃), or YBCO(YbBa₂Cu₃O₇).

10. The method of manufacturing a semiconductor memory device, according to claim 1, wherein
the material of the upper electrode lines contains at least one material selected from the group consisting of a noble metal of platinum group metals; a metal selected from Ag, Al, Cu, Ni, Ti, or Ta; an alloy of the metal; an electrically conductive oxide of Ir, Ru, Re, or Os; and SRO(SrRuO₃), LSCO((LaSr)CoO₃), or YBCO(YbBa₂Cu₃O₇).

11. A method of manufacturing a semiconductor memory device which has an array of memory cells arranged in a cross point structure including a plurality of upper electrode lines patterned to extend in one direction, a plurality of lower electrode lines patterned to extend at a right angle to the one direction of the upper electrode lines, insulating layers provided on both sides of the lower electrode lines and memory elements provided between the upper electrode lines and the lower electrode lines for storage of data, comprising:
forming the lower electrode lines by planarizing each of the lower electrode lines and insulating layers provided on both sides of the lower electrode line so as to be substantially uniform in the height and suitable for patterning the lower electrode lines;
depositing the memory element layer by depositing on the lower electrode lines a memory element layer which is formed into the memory elements; and
annealing by annealing with heat treatment after depositing the memory element layer.

12. The method of manufacturing a semiconductor memory device according to claim 11, wherein
the heat treatment in the annealing step is carried out at a heating temperature ranging from 300° C. to 800° C.

13. The method of manufacturing a semiconductor memory device, according to claim 11, further comprising:
depositing the second electrode layer by depositing on the memory element layer a second electrode layer which is formed into the upper electrode lines;
forming the upper electrode lines by etching the second electrode layer to pattern the upper electrode lines;
forming the memory elements by etching the memory element layer remaining between the upper electrode lines to pattern the memory elements; and
a second annealing by annealing with heat treatment after the memory elements forming step.

14. The method of manufacturing a semiconductor memory device, according to claim 13, wherein
the heat treatment in the second annealing step after the memory elements forming step is carried out at a beating temperature ranging from 300° C. to 800° C.

15. The method of manufacturing a semiconductor memory device, according to claim 11, wherein
forming the lower electrode lines comprises the sub steps of:
depositing on a semiconductor substrate a first electrode layer which is formed into the lower electrode lines;
etching the first electrode layer to pattern the lower electrode lines;
depositing the insulating layer on the lower electrode lines; and
polishing down the insulating layer until the lower electrode lines are exposed at the upper surface.

16. The method of manufacturing a semiconductor memory device, according to claim 11, wherein
forming the lower electrode lines comprises the sub steps of:
depositing the insulating layer on a semiconductor substrate;
processing the insulating layer to have a stripe form of steps;
depositing on the insulating layer with the stripe form of steps a first electrode layer which is formed into the lower electrode lines; and
polishing down the first electrode layer until the insulating layer is exposed at the upper surface.

17. The method of manufacturing a semiconductor memory device, according to claim 11, wherein
the memory element layer is made of a perovskite oxide material which includes at least one element selected from the group consisting of Pr, Ca, La, Sr, Gd, Nd, Bi, Ba, Y, Ce, Pb, Sm, and Dy and at least another element selected from the group consisting of Ta, Ti, Cu, Mn, Cr, Co, Fe. Ni, and Ga.

18. The method of manufacturing a semiconductor memory device, according to claim 11, wherein
the memory element layer is made of a perovskite oxide material which is expressed by any one of formulas (where 0≦x≦1 and 0≦z<1 ) selected from the group consisting of:
Pr_{1-X}Ca_{X}[Mn_{1-Z}M_{Z}]O₃ (M being any one of elements selected from Cr, Co, Fe, Ni, and Ga),
La_{1-X}AE_{X}MnO₃ (AE being any one of bivalent alkali earth metals selected from Ca, Sr, Pb, and Ba),
RE_{1-X}Sr_{X}MnO₃ (RE being any one of trivalent rare earth elements selected from Sm, La, Pr, Nd, Gd, and Dy),
La_{1-X}Co_{X}[Mn_{1-Z}Co_{Z}]O₃,
Gd_{1-X}Ca_{X}MnO₃, and
Nd_{1-X}Gd_{X}MnO₃.

19. The method of manufacturing a semiconductor memory device, according to claim 11, wherein
the material of the lower electrode lines contains at least one material selected from the group consisting of a noble metal of platinum group metals; an alloy of the noble metal; an electrically conductive oxide of Ir, Ru, Re, or Os; and SRO(SrRuO₃), LSCO(LaSr)CoO₃), or YBCO(YbBa₂Cu₃O₇).

20. The method of manufacturing a semiconductor memory device, according to claim 11, wherein
the material of the upper electrode lines contains at least one material selected from the group consisting of a noble metal of platinum group metals; a metal selected from Ag, Al, Cu, Ni, Ti, or Ta; or an alloy of the metal, an electrically conductive oxide of Ir, Ru, Re, or Os; and SRO(SrRuO₃), LSCO((LaSr)CoO₃), or YBCO(YbBa₂Cu₃O₇).

21. A method of manufacturing a semiconductor memory device which has an array of memory cells arranged in a cross point structure including a plurality of upper electrode lines patterned to extend in one direction, a plurality of lower electrode lines patterned to extend at a right angle to the one direction of the upper electrode lines, insulating layers provided on both sides of the lower electrode line and memory elements provided between the upper electrode lines and the lower electrode lines for storage of data, comprising:
forming the lower electrode lines by planarizing each of the lower electrode lines and insulating layers provided on both sides of the lower electrode line so as to be uniform in the height and suitable for patterning the lower electrode lines;
depositing the memory element layer by depositing on the lower electrode lines a memory element layer which is formed into the memory elements;
depositing the second electrode layer by depositing on the memory element layer a second electrode layer which is formed into the upper electrode lines;
forming the upper electrode lines by etching the second electrode layer to pattern the upper electrode lines;
forming the memory elements by etching the memory element layer remaining between the upper electrode lines to pattern the memory elements; and
annealing by annealing with heat treatment after the memory elements forming step.

22. The method of manufacturing a semiconductor memory device according to claim 21, wherein
the heat treatment in the annealing step is carried out at a heating temperature ranging from 300° C. to 800° C.

23. The method of manufacturing a semiconductor memory device, according to claim 21, wherein
forming the lower electrode lines comprises the sub steps of:
depositing on a semiconductor substrate a first electrode layer which is formed into the lower electrode lines;
etching the first electrode layer to pattern the lower electrode lines;
depositing the insulating layer on the lower electrode lines; and
polishing down the insulating layer until the lower electrode lines are exposed at the upper surface.

24. The method of manufacturing a semiconductor memory device, according to claim 21, wherein
forming the lower electrode lines comprises the sub steps of:
depositing the insulating layer on a semiconductor substrate;
processing the insulating layer to have a stripe form of steps;
depositing on the insulating layer with the stripe form of steps a first electrode layer which is formed into the lower electrode lines; and
polishing down the first electrode layer until the insulating layer is exposed at the upper surface.

25. The method of manufacturing a semiconductor memory device, according to claim 21, wherein
the memory element layer is made of a perovskite oxide material which includes at least one element selected from the group consisting of Pr, Ca, La, Sr, Gd, Nd, Bi, Ba, Y, Ce, Pb, Sm, and Dy and at least another element selected from the group consisting of Ta, Ti, Cu, Mn, Cr, Co, Fe, Ni, and Ga.

26. The method of manufacturing a semiconductor memory device, according to claim 21, wherein
the memory element layer is made of a perovskite oxide material which is expressed by any one of formulas (where 0≦x≦1 and 0≦z<1) selected from the group consisting of:
Pr_{1-X}Ca_{X}[Mn_{1-Z}M_{Z}]O₃ (M being any one of elements selected from Cr, Co, Fe, Ni, and Ga),
La_{1-X}AE_{X}O₃ (AE being any one of bivalent alkali earth metals selected from Ca, Sr, Pb, and Ba),
RE_{1-X}Sr_{X}MnO₃ (RE being any one of trivalent rare earth elements selected from Sm, La, Pr, Nd, Gd, and Dy),
La_{1-X}Co_{X}[Mn_{1-Z}Co_{Z}]O₃,
Gd_{1-X}Ca_{X}MnO₃, and
Nd_{1-X}Gd_{X}MnO₃.

27. The method of manufacturing a semiconductor memory device, according to claim 21, wherein
the material of the lower electrode lines contains at least one material selected from the group consisting of a noble metal of platinum group metals; an alloy of the noble metal; an electrically conductive oxide of Ir, Ru, Re, or Os; and SRO(SrRuO₃), LSCO((LaSr)CoO₃), or YBCO(YbBa₂Cu₃O₇).

28. The method of manufacturing a semiconductor memory device, according to claim 21, wherein
the material of the upper electrode lines contains at least one material selected from the group consisting of noble metal of platinum group metals; a metal selected from Ag, Al, Cu, Ni, Ti, or Ta; an alloy of the metal; an electrically conductive oxide of Ir, Ru, Re, or Os; a SRO(SrRuO₃), LSCO((LaSr)CoO₃), or YBCO(YbBa₂Cu₃O₇).
